(19) United States
(12) Patent Application Publication
(10) Pub. No.: US 2006/0216896 A1
(43) Pub. Date: Sep. 28, 2006

(54) Semiconductor device and method for manufacturing same

(75) Inventors: Wataru Saito, Kawasaki-shi (JP); Ichiro Omura, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/363,047

(22) Filed: Feb. 28, 2006

(30) Foreign Application Priority Data
Mar. 24, 2005 (JP) 2005-85435

(51) Int. Cl. H01L 21/8242; H01L 21/336

(52) U.S. Cl. 438/270; 438/272

(57) ABSTRACT

The present semiconductor device comprises pillar layers formed on a semiconductor substrate, the pillar layers comprising a first semiconductor pillar layer of a first conductivity type and a second semiconductor pillar layer of a second conductivity type which both have a strip cross section and are alternately formed on the semiconductor surface. A semiconductor base layer of the second conductivity type is selectively formed on one of the first semiconductor pillar layer and second semiconductor pillar layer. The semiconductor base layer has a flat impurity profile.

### CROSS REFERENCE TO RELATED APPLICATIONS

This application is based on and claims the benefit of priority from prior Japanese Patent Application No. 2005-85435, filed on Mar. 24, 2005, the entire contents of which are incorporated herein by reference.

### BACKGROUND OF THE INVENTION

1. Field of the Invention

The present invention relates to a semiconductor device and a method for manufacturing the same, and more particularly, to a semiconductor device including a so-called super junction structure and method for manufacturing the same.

2. Description of the Related Art

The on-resistance of the vertical power MOSFET depends largely on the electrical resistance in the conduction layer (drift layer) portion. The electrical resistance of the drift layer depends on its impurity concentration. A higher impurity concentration can provide a lower on-resistance. A higher impurity concentration, however, will decrease the breakdown voltage of the PN junction between the drift layer and base layer. The impurity concentration thus cannot be higher than a limit determined by the breakdown voltage. A trade-off relation therefore exists between the device breakdown voltage and on-resistance. An improved trade-off is important to provide a power semiconductor device with lower power consumption. The trade-off has a limit depending on the device material. Exceeding the limit is required to provide a power semiconductor device with low on-resistance.

One known example of the MOSFET to solve this problem has a structure in which the drift layer has a so-called super junction structure. The super junction structure includes a p-type pillar layer and a n-type pillar layer, which are of a vertically-oriented strip, and are alternately embedded in the drift layer in the lateral direction (see, for example, Japanese application patent laid-open publication No. 2003-273355). The super junction structure includes the same charge amount (impurity amount) in the p-type pillar layer and n-type pillar layer to provide a pseudo-non-doped layer which keeps the high breakdown voltage. The structure also carries a current through the highly doped n-type pillar layer to provide the low on-resistance over the material limit.

The super junction structure can thus provide the on-resistance/breakdown voltage trade-off over the material limit. Improvement of this trade-off, i.e., the lower on-resistance, however, requires a smaller lateral interval (pitch) of the super junction structure. The smaller width can facilitate the depletion of the pn junction in the non-conducting state. This allows for the higher impurity concentration in the pillar layer.

In this case, in addition to the super junction structure, the MOSFET gate structure formed thereon needs to have the smaller lateral interval (cell pitch), accordingly. A shorter channel is indispensable to provide the smaller cell pitch in the MOSFET gate structure. The p-type base layer with a shallower junction depth can provide the shorter channel.

The p-type base layer with a smaller junction depth, however, will increase its curvature in the device region end portion. This may cause electric field concentration in that portion, which can decrease the breakdown voltage and cause destruction of the device. The smaller cell pitch with a sufficient breakdown voltage thus requires the p-type base layer which has sufficient vertical (in-depth) diffusion with suppressed lateral diffusion.

Even if such a deep p-type base layer is realizable, the diffusion process may diffuse the impurities in the pn pillar layer under the base layer. This will reduce the effective impurity concentration of the super junction structure, which may increase the on-resistance. An impurity concentration increase to complement the increase in the on-resistance will increase the variation in the impurity doping amount during processes, which increases the variation in the breakdown voltage.

### SUMMARY OF THE INVENTION

A semiconductor device according to one aspect of the invention comprises: a semiconductor substrate of a first conductivity type; pillar layers formed on the semiconductor substrate, the pillar layers comprising a first semiconductor pillar layer of a first conductivity type and a second semiconductor pillar layer of a second conductivity type which both have a strip cross section and are alternately formed in a first direction along a surface of the semiconductor substrate; a first main electrode electrically connected to the first semiconductor substrate; a semiconductor base layer of the second conductivity type selectively formed on a surface of one of the first semiconductor pillar layer and second semiconductor pillar layer; a semiconductor diffusion layer of the first conductivity type selectively diffused into a surface of the semiconductor base layer; a second main electrode formed in contact with the semiconductor base layer and semiconductor diffusion layer; and a control electrode formed via an insulating film on a region over the semiconductor diffusion layer and first semiconductor pillar layer to form a channel between the semiconductor diffusion layer and first semiconductor pillar layer, and the semiconductor base layer having an impurity profile which is flat at least in the first direction.

A method for manufacturing a semiconductor device according to one aspect of the invention is a method for manufacturing a semiconductor device comprising pillar layers formed on a first semiconductor layer of a first conductivity type, the pillar layers comprising a first semiconductor pillar layer of the first conductivity type and a second semiconductor pillar layer of a second conductivity type which are alternately formed in a first direction along a surface of the first semiconductor layer, the method comprising the steps of: growing an epitaxial layer for the pillar layers on the semiconductor substrate of the first conductivity type; forming a semiconductor base layer of the second conductivity type on the epitaxial layer over a whole area of a device portion by diffusion; forming a trench which passes through the semiconductor layer and reaches at least near a bottom of the epitaxial layer; depositing in the trench a semiconductor layer of an opposite conductivity type to the epitaxial layer to form the pillar layer; and forming a diffusion region, an insulating film, and an electrode in the semiconductor base layer divided by the trench to form the semiconductor device.

### BRIEF DESCRIPTION OF THE DRAWINGS

FIG. 1 is a cross sectional view of the vertical power MOSFET device structure with the super junction structure according to the first embodiment of the present invention.

FIG. 2 is a process chart of the manufacturing method of the power MOSFET in FIG. 1.

FIG. 3 is another process chart of the manufacturing method of the power MOSFET in FIG. 1.

FIG. 4 is another process chart of the manufacturing method of the power MOSFET in FIG. 1.

FIG. 5 is another process chart of the manufacturing method of the power MOSFET in FIG. 1.

FIG. 6 is another process chart of the manufacturing method of the power MOSFET in FIG. 1.

FIG. 7 is another process chart of the manufacturing method of the power MOSFET in FIG. 1.

FIG. 8 is another process chart of the manufacturing method of the power MOSFET in FIG. 1.

FIG. 9 is another process chart of the manufacturing method of the power MOSFET in FIG. 1.

FIG. 10 is a cross sectional view of the vertical power MOSFET device structure with the super junction structure according to the second embodiment of the present invention.

FIG. 11 is a cross sectional view of the vertical power MOSFET device structure with the super junction structure according to a modified example of the second embodiment of the present invention.

FIG. 12 is a cross sectional view of the vertical power MOSFET device structure with the super junction structure according to the third embodiment of the present invention.

FIG. 13 is a cross sectional view of the vertical power MOSFET device structure with the super junction structure according to a modified example of the third embodiment of the present invention.

FIG. 14 is another cross sectional view of the vertical power MOSFET device structure with the super junction structure according to a modified example of the third embodiment of the present invention.

FIG. 15 is a cross sectional view of the vertical power MOSFET device structure with the super junction structure according to the fourth embodiment of the present invention.

FIG. 16 is a plan view of the vertical power MOSFET device structure with the super junction structure according to the fifth embodiment of the present invention.

FIG. 17 is a plan view of the vertical power MOSFET device structure with the super junction structure according to a modified example of the fifth embodiment of the present invention.

FIG. 18 is a plan view of the vertical power MOSFET device structure with the super junction structure according to a modified example of the fifth embodiment of the present invention.

FIG. 19 is a cross sectional view of the vertical power MOSFET device structure, particularly the end region, with the super junction structure according to the sixth embodiment of the present invention.

FIG. 20 is a cross sectional view of the vertical power MOSFET device structure, particularly the end region, with the super junction structure according to a modified example according to the sixth embodiment of the present invention.

FIG. 21 is a cross sectional view of the vertical power MOSFET device structure, particularly the end region, with the super junction structure according to another modified example according to the sixth embodiment of the present invention.

### DETAILED DESCRIPTION OF THE EMBODIMENTS

Embodiments of the present invention will be described below with reference to drawings. Note that the following embodiments assume that the first conductivity type is the n-type, and the second conductivity type is the p-type. In the drawings, identical elements are designated with like reference numbers.

### First Embodiment

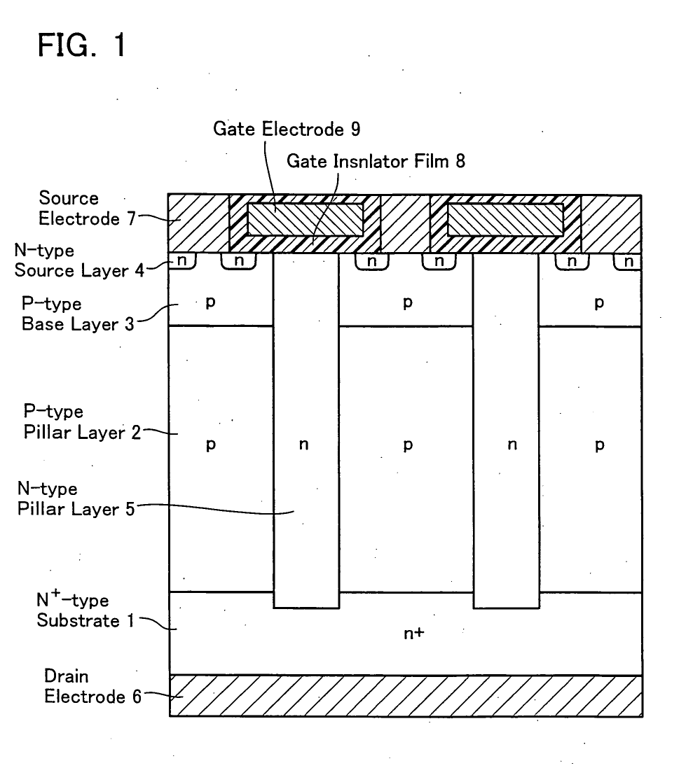

FIG. 1 is a schematical cross sectional view of the configuration of the vertical power MOSFET according to the first embodiment of the present invention. The power MOSFET has a super junction structure formed over the n⁺-type substrate 1 which functions as the drain layer. The super junction structure includes an n-type pillar layer 5 and p-type pillar layer 2, which both have a strip cross section and are formed alternately in the lateral direction (the first direction) along the surface of the n⁺-type substrate 1. A drain electrode 6 is formed under the n⁺-type substrate 1. Formed on the surfaces of the p-type pillar layers 2 are a plurality of p-type base layers 3, each having both sides divided by the n-type pillar layer 5. On each surface of the divided p-type base layers 3, an n-type source layer 4 is selectively formed in a stripe shape, such that the n-type pillar layer 5 and n-type source layer 4 have substantially flush top faces.

A gate electrode 9 in a stripe shape is formed via a gate insulator film 8 on the n-type source diffusion layer 4, p-type base layer 3, and n-type pillar layer 5. More specifically, the gate electrode 9 is formed as a so-called planar gate structure which forms a lateral channel between the n-type source diffusion layer 4 and n-type pillar layer 5. With reference to FIG. 1, the gate insulator film 8 and gate electrode 9 can be commonly formed on the adjacent two p-type base layers 3 opposite across one n-type pillar layer 5. The gate insulator film 8 may be, for example, a silicon oxide film with a thickness of about 0.1 um.

A source electrode 7 common to each MOSFET connects to the p-type base layer 3 and n-type source diffusion layer 4. The gate insulator film 8 or the like isolates the source electrode 7 from the gate electrode 9.

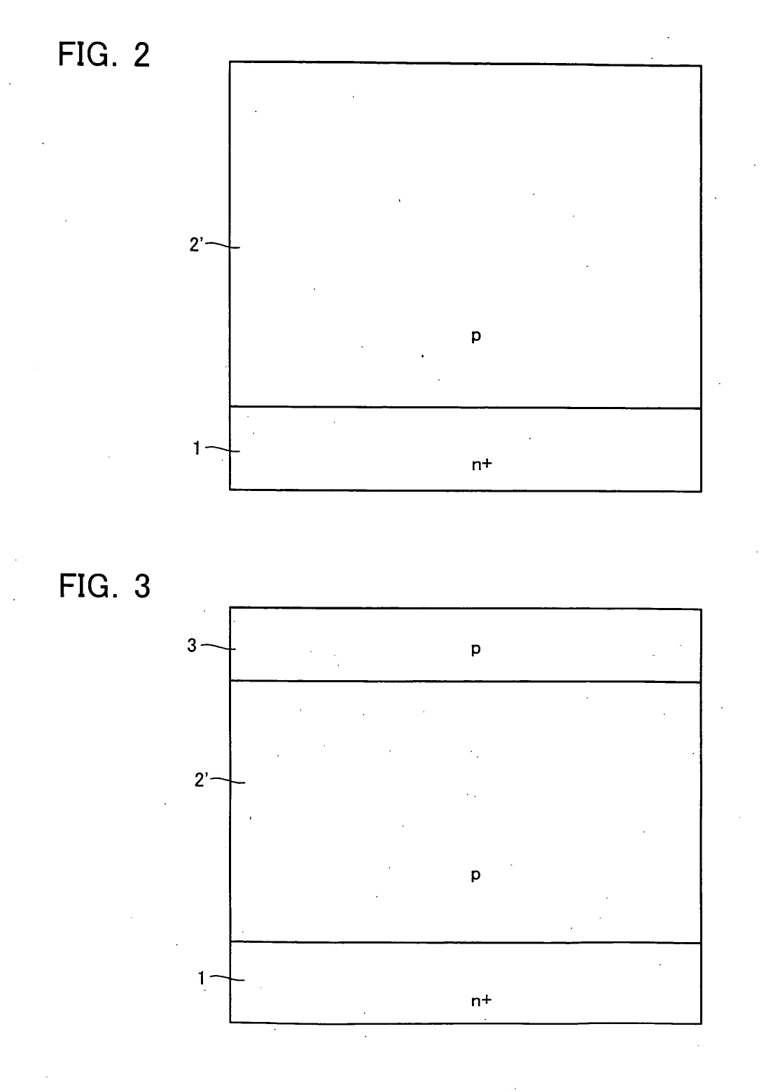

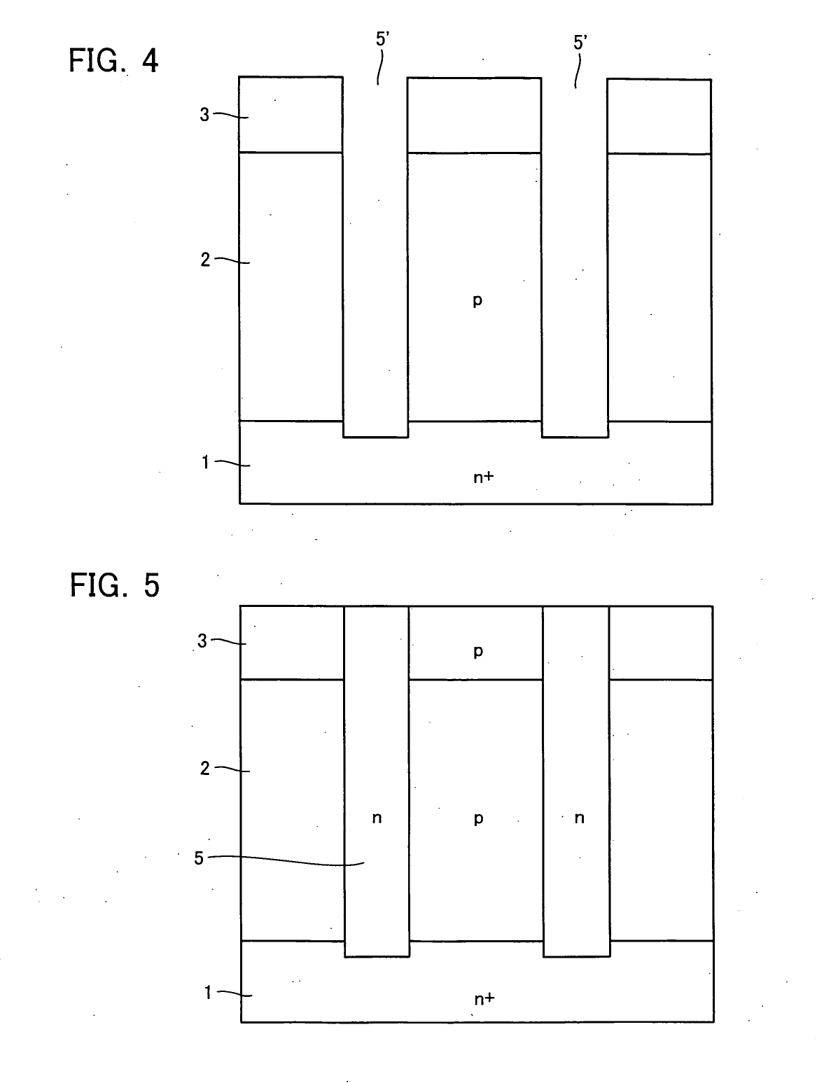

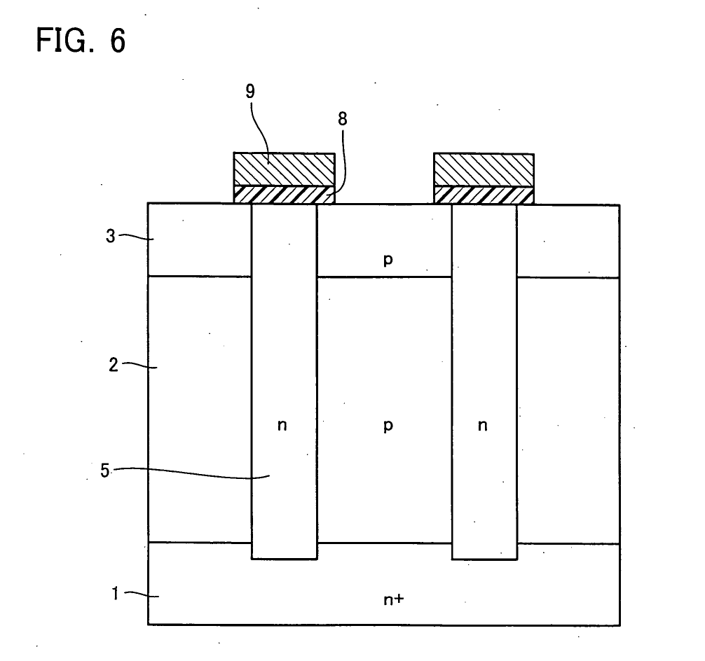

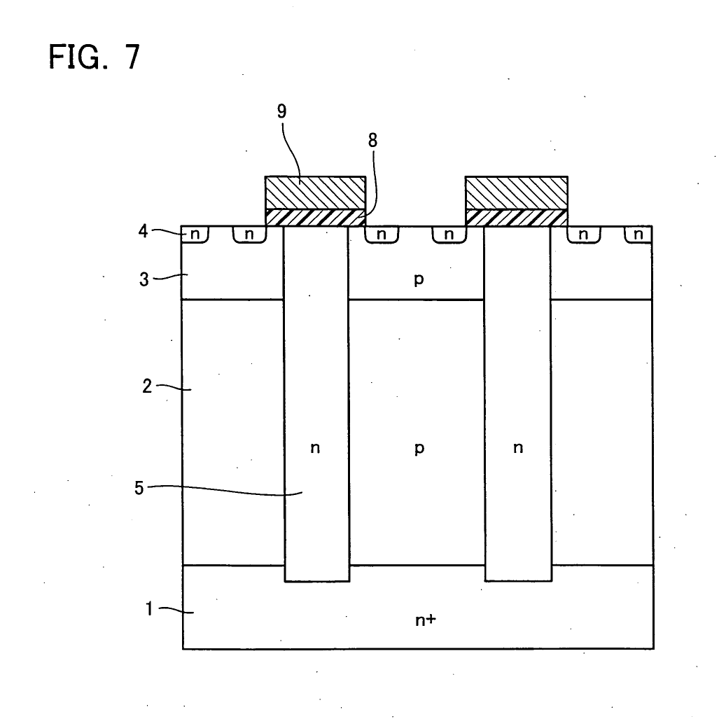

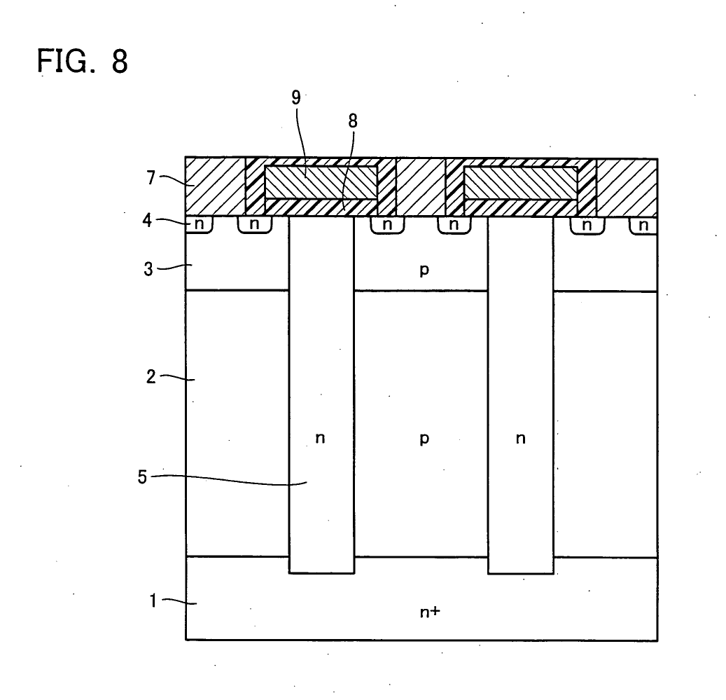

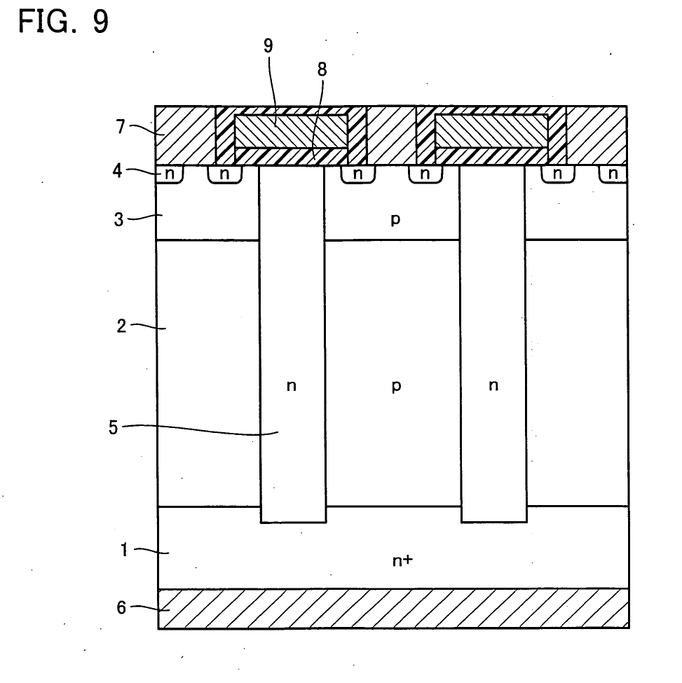

Processes shown in FIGS. 2 to 9 can form the structure shown in FIG. 1. More specifically, as shown in FIG. 2, a p-type epitaxial layer 2′ for the p-type pillar layers 2 is epitaxially grown on the n⁺-type substrate 1. Then, as shown in FIG. 3, the p-type base layer 3 is formed over the whole surface of the p-type epitaxial layer 2′ in the device main cell region by ion injection and thermal diffusion. Because the super junction structure is not formed yet at this point, there are no problems with the deep p-type base layer 3 being formed with a thermal process with a high temperature for a long time. This can form the deep p-type base layer 3. Then, as shown in FIG. 4, a plurality of trenches 5′ are formed reaching the n⁺-type substrate 1 through the p-type base layer 3 and p-type epitaxial layer 2′. Then, as shown in FIG. 5, an n-type semiconductor layer for the n-type pillar layer 5 is embedded in the trench 5′ by crystal growth. Then, the gate electrode 9 is formed on top of the n-type pillar layer 5 via the gate insulator film 8 (FIG. 6). Then, the n-type source layer 4 in a stripe shape is selectively formed in the p-type base layer 3 (FIG. 7). Then, the source electrode 7 and drain electrode 6 can be formed in this order (FIG. 8, FIG. 9) to complete the MOSFET with the super junction structure.

In the above processes, after the n-type pillar layer 5 is formed, i.e., the super junction structure is formed, subsequent thermal processes are only the formation of the gate oxide film 8, and the diffusion of the n-type source layer 4. These processes are done at lower temperatures and shorter time than the process for the p-type base layer 3. These processes may thus provide little diffusion of the impurity in the super junction structure. The above processes can therefore suppress the reduction of the effective impurity concentration in the super junction structure during the thermal processes, thereby providing the power MOSFET with a suppressed increase in the on-resistance. Also in the above processes, the p-type base layer 3 is formed over the whole surface of the device portion on the p-type epitaxial layer 2′ by diffusion, and then is divided during the formation of the trench 5′ to be formed as a layer left on the p-type pillar layer 2, so that the layer 3 rarely diffuses laterally. The p-type base layer 3 thus has a flat impurity profile in the lateral direction. The p-type base layer 3 and p-type pillar layer 2 have the same width and substantially flush side faces. The above processes can thus decrease the channel length of the MOSFET, and can easily decrease the MOSFET cell pitch.

### Second Embodiment

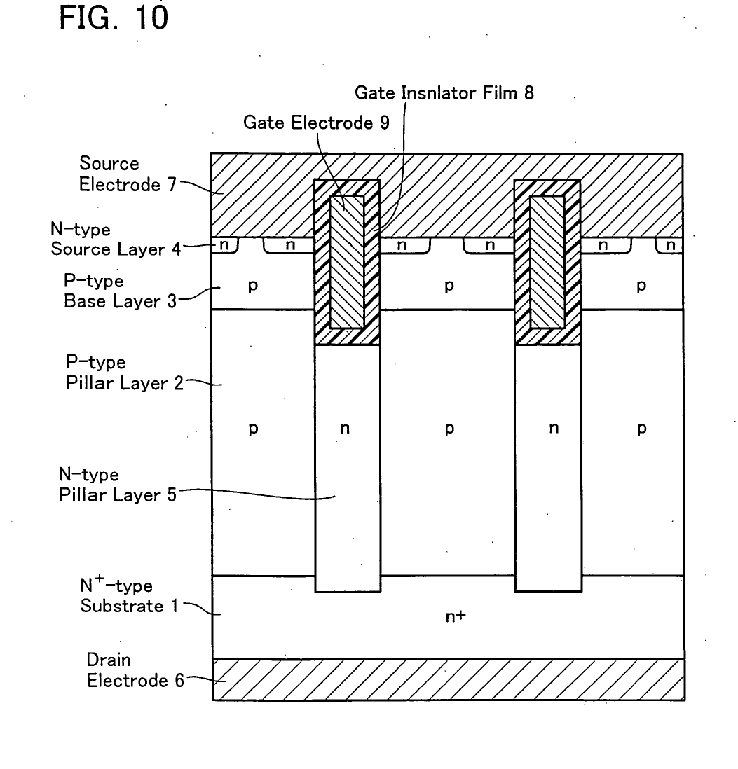

FIG. 10 is a schematical cross sectional view of the configuration of the vertical power MOSFET according to the second embodiment of the present invention. The same configuring members as those in the first embodiment are given the same reference numerals for omitting the detailed description thereof. This embodiment differs from the first embodiment in that the gate electrode 9 of the MOSFET has the so-called trench gate structure, compared to the planar gate structure in the first embodiment. More specifically, the gate electrode 9 is formed via the gate insulator film 8 along the side face of the p-type base layer 3 and has a vertical longitudinal direction. The gate electrode 9 forms a vertical channel.

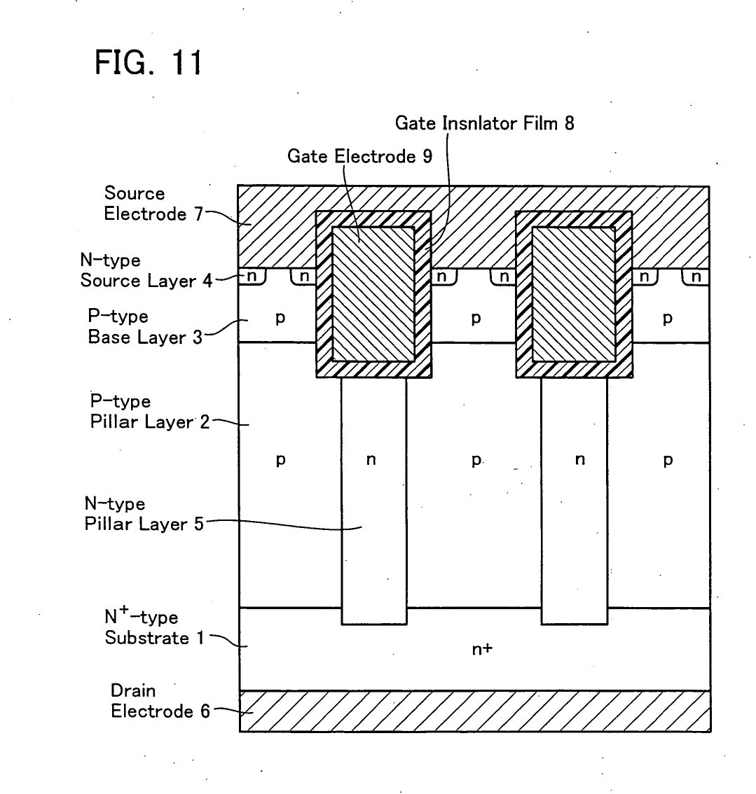

For the planar gate structure as in the first embodiment, a misalignment between the p-type base layer 3 and gate electrode 9 may cause variation in the channel length. For the trench gate structure in FIG. 2, the channel length depends on the diffusion depth of the p-type base layer 3. The channel length can thus be unaffected by the misalignment and have less variation. Note that as shown in FIG. 11, the gate electrode 9 with a larger lateral width than the n-type pillar layer 5 can ensure a vertically-extending channel formed in the p-type base layer 3 between the n-type source layer 4 and n-type pillar layer 5.

### Third Embodiment

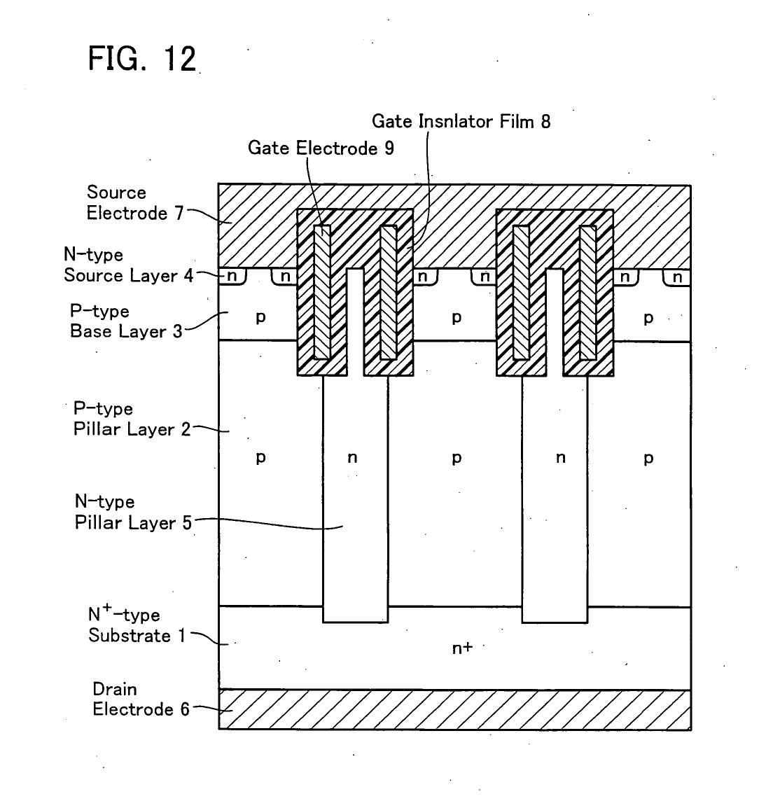

FIG. 12 is a schematical cross sectional view of the configuration of the vertical power MOSFET according to the third embodiment of the present invention. The same configuring members as those in the first embodiment are given the same reference numerals for omitting the detailed description thereof. This embodiment forms the MOSFET with the trench gate structure, as in the second embodiment. Note, however, that this embodiment differs from the second embodiment in that two gate electrodes 9 are formed for one n-type pillar layer 5.

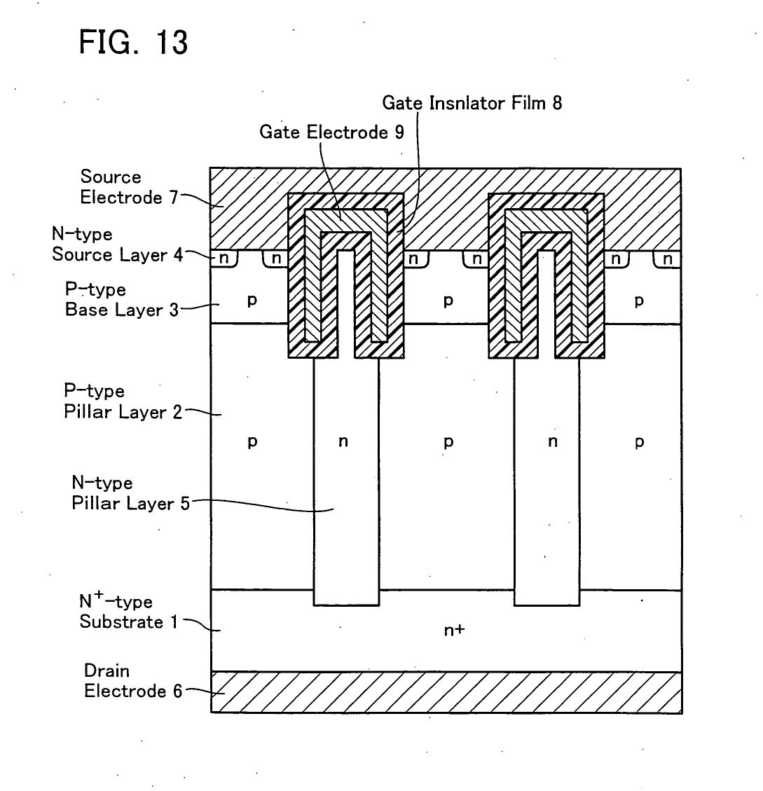

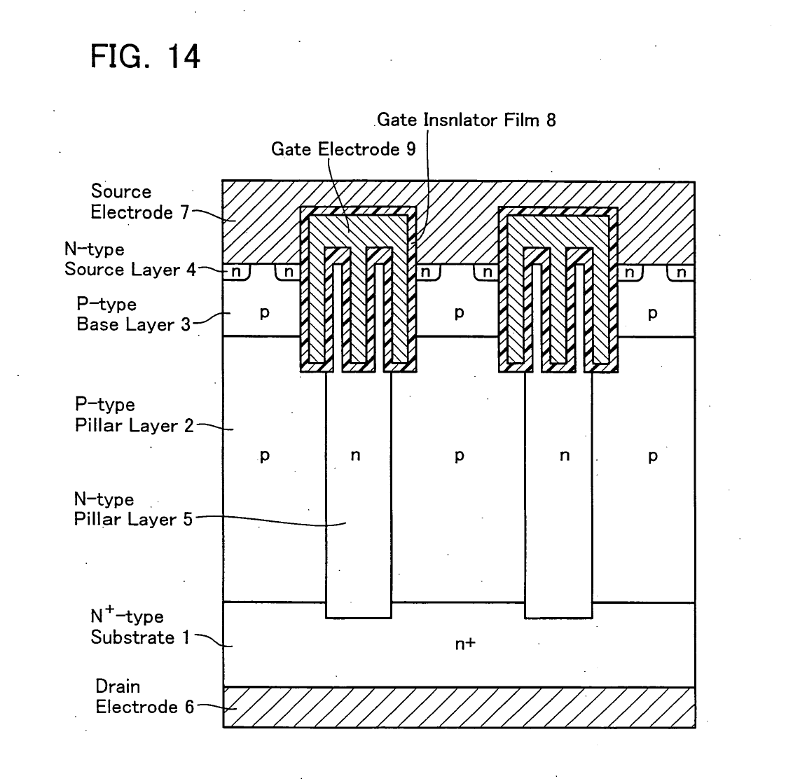

This trench gate structure can be formed by, for example, embedding the n-type pillar layer 5, and then forming two trenches corresponding to the number of the gate electrode 9 which is to be formed on the n-type pillar layers, and embedding the gate insulator film 8 and gate electrode 9 into each trench. In this way, the trench can be formed for each of the plurality of gate electrodes 9 with a narrower trench width than when the trench is formed over the entire. The narrower trench width can facilitate the embedding of the insulating film or the like into the trench 5′, thereby decreasing the process time. Note that as shown in FIG. 13, the two gate electrodes 9 may be integrated into one gate electrode in a downward-facing horseshoe shape which covers the n-type pillar layer 5. This can decrease the electric field around the gate electrode 9 and the electrical stress in the gate insulator film 8, and can provide a larger surface area of the gate electrode 9, which can decrease the gate lead resistance. Note that the number of the gate electrode 9 formed over one n-type pillar layer 5 may be two, as well as three or more, as shown in FIG. 14.

### Fourth Embodiment

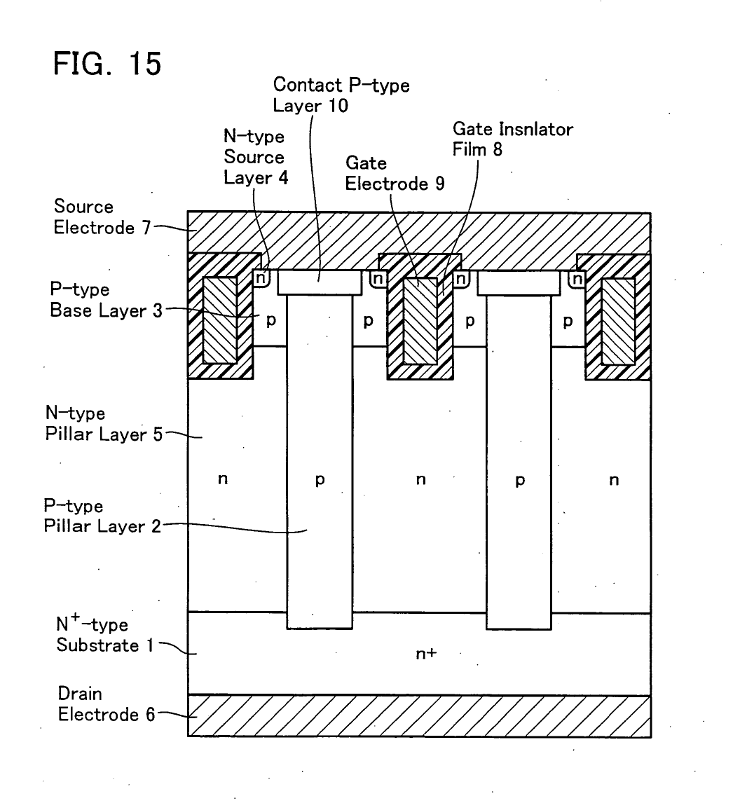

FIG. 15 is a schematical cross sectional view of the configuration of the vertical power MOSFET according to the fourth embodiment of the present invention. The same configuring members as those in the first embodiment are given the same reference numerals for omitting the detailed description thereof. The above first to third embodiments show a structure formed by forming the trench in the p-type epitaxial layer, and by embedding the n-type pillar layer 5 into the trench to form the pn pillar layer.

This embodiment differs from the above embodiments in that it shows a structure formed by forming the trench in the n-type epitaxial layer, and by embedding the p-type pillar layer 2 into the trench to form the pn pillar layer. More specifically, the n-type epitaxial layer is formed on the n⁺-type substrate 1, the p-type base layer 3 is formed on the n-type epitaxial layer, and the trench is formed penetrating the p-type base layer 3 and n-type epitaxial layer. The p-type semiconductor layer is then embedded into the trench to form the p-type pillar layer 2. The MOSFET gate structure is then formed. Such a structure of the pn pillar layer and a process can still form the sufficiently deep p-type base layer 3 and can also provide the uniform impurity profile in the lateral direction, which can suppress the increase in the on-resistance due to the impurity diffusion of the pn pillar layer. Note, however, that this embodiment uses the trench gate structure rather than the planar-gate structure as the MOSFET gate structure, because the n-type pillar layer 5 resides under the p-type base layer. In the trench gate structure shown in FIG. 15, the gate insulator film 8 and gate electrode 9 divide the p-type base layer 3, providing a smaller contact area between the source electrode 7 and p-type base layer 3, accordingly. To decrease the contact resistance, a p⁺-type contact layer 10 is preferably provided between the p-type base layer 3 and source electrode 7.

### Fifth Embodiment

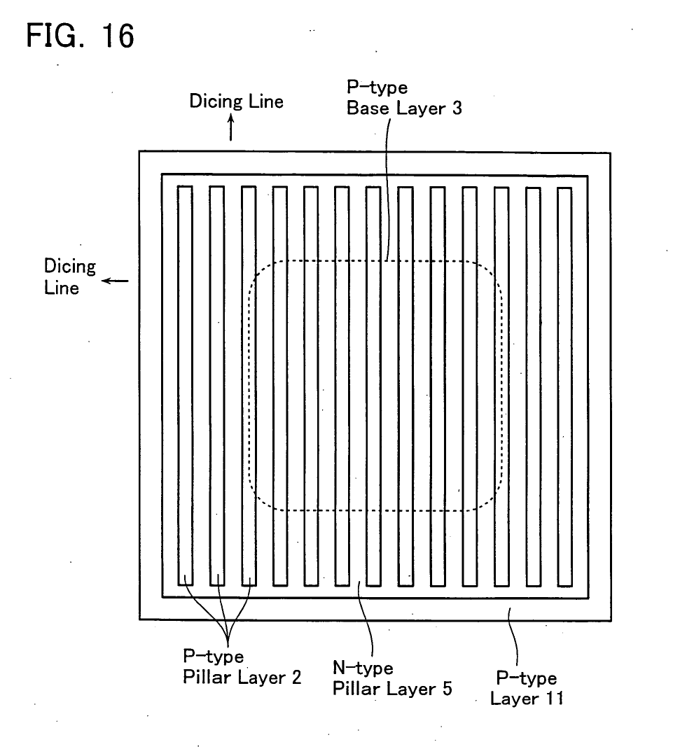

FIG. 16 is a schematical top view of the configuration of the vertical power MOSFET according to the fifth embodiment of the present invention. With reference to FIG. 16, in the device region (where the p-type base layer 3 is formed) and the end region, the p-type pillar layer 2 and n-type pillar layer 5 are alternately formed in a stripe pattern around which the n-type pillar layer 5 is formed. Such a plane pattern can provide a stable operation of the power MOSFET. A voltage applied to the MOSFET with the super junction structure allows the depletion layers to extend from all the junction faces of the p/n pillar layers. The depletion layer can extend even into the end region, i.e., in the outside of the p-type base layer 3, because p-type pillar layers 2 is connected thereto. If, therefore, the p-type pillar layer 2 has a periphery in contact with the dicing line, the voltage will be applied to the connection, thereby contributing to the leak. Therefore, as shown in FIG. 16, the n-type pillar layer 5 surrounds the stripe portion to prevent the p-type pillar layer 2 from reaching the dicing line, thereby helping to separate the portion from the dicing line.

The n-type pillar layer 5 is formed by embedding the n-type semiconductor layer into the trench formed in the p-type epitaxial layer. The n-type pillar layer 5 surrounding the periphery of the above stripe shape portion and the n-type pillar layer 5 in the stripe shape portion can be formed at the same time by forming the trenches at the same time and then carrying out the embedding and crystal growth in the trench. Note, however, that when the n-type pillar layer 5 surrounding the periphery and the n-type pillar layer 5 in the stripe shape portion are embedded at the same time, the same level of the trench width is required for the pillar layers 5. For the same-level trench width, however, it is difficult to form the entire periphery including the dicing line using the n-type pillar layer 5. This embodiment thus forms a p-type layer 11 around the n-type pillar layer 5 which surrounds the periphery of the stripe shape portion. This can prevent the depletion layer from extending outside even when the n-type pillar layer 5 has the same level of the width at the periphery and in the stripe shape portion.

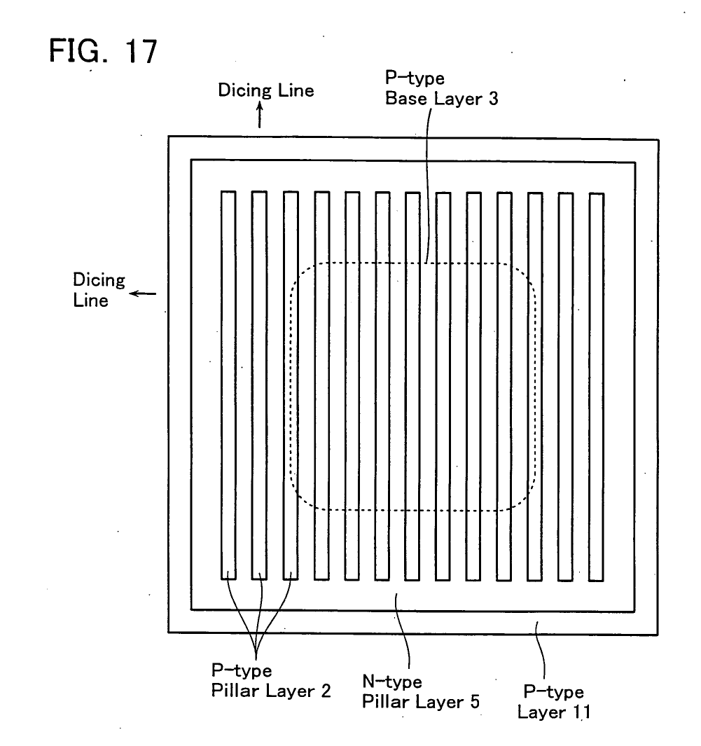

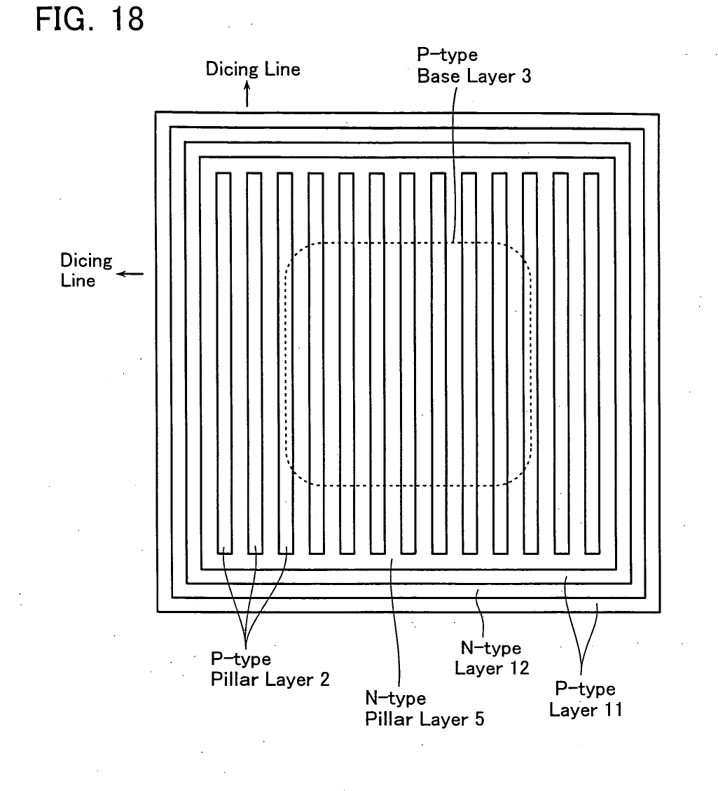

With reference to FIG. 17, the n-type pillar layer 5 at the periphery can be embedded and formed in a different process from that for the n-type pillar layer 5 in the stripe shape portion, thereby allowing the n-type pillar layer 5 at the periphery to have a wider width than the n-type pillar layer 5 in the stripe shape portion. Also, with reference to FIG. 18, the p-type layer 10 can have around it an n-type layer 12 and another p-type layer 11 to further securely prevent the extension of the depletion layer. It is also possible to have a plurality of repetitions of the n-type layer 12 and p-type layer 11. Note that in the structures of FIGS. 16 to 18, the gate structure of the MOSFET may be a planar gate structure or a trench gate structure.

### Sixth Embodiment

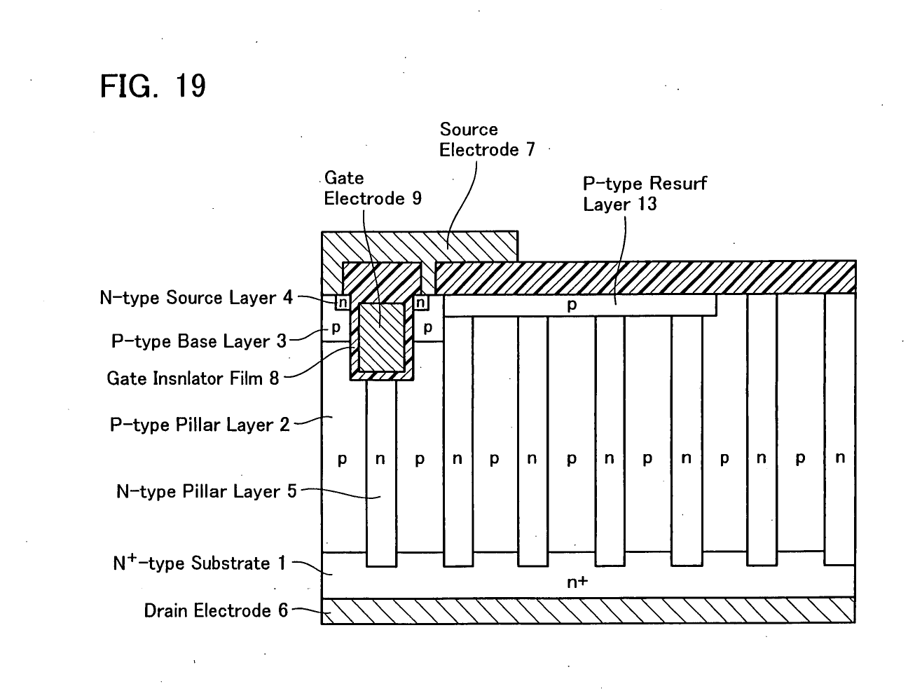

FIG. 19 is a schematical cross sectional view of the configuration of the vertical power MOSFET according to the sixth embodiment of the present invention. The same configuring members as those in the first embodiment are given the same reference numerals for omitting the detailed description thereof. With reference to FIG. 19, the power MOSFET in this embodiment has the pn pillar layers including the p-type pillar layer 2 and n-type pillar layer 5 which are formed in the device region as well as in the end region. In addition, a p-type resurf layer 13 is formed on the surface of the pn pillar layer in the end region. A voltage applied to the MOSFET will allow the depletion layer to extend laterally along the p-type resurf layer 13. This depletion layer can reduce the electric field concentration in the p-type base layer 3 end portion, thereby providing the MOSFET with the high breakdown voltage.

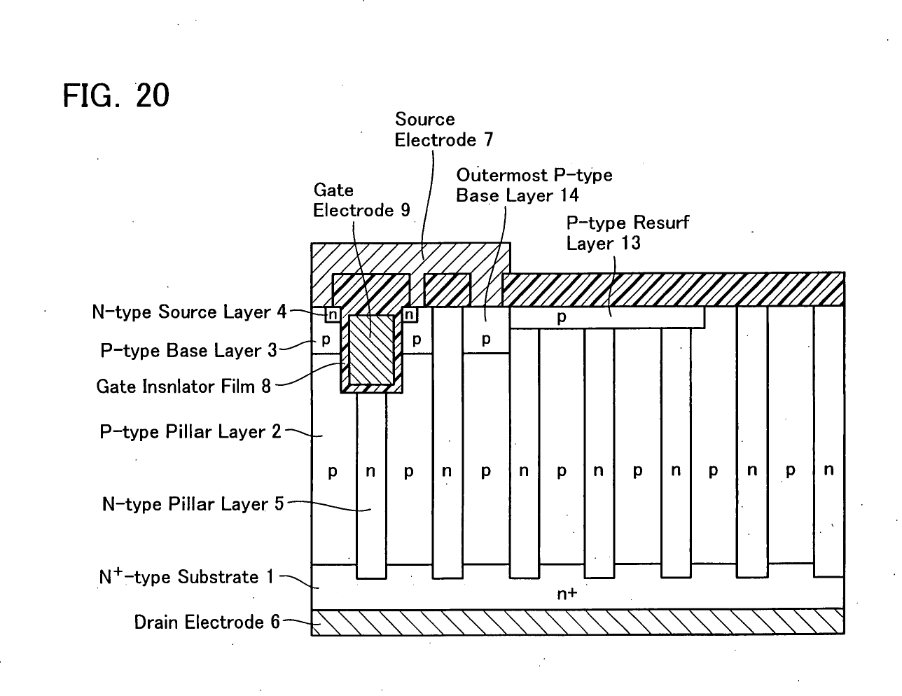

FIG. 20 shows a modified example of the sixth embodiment. In this modified example, the outermost p-type base layer 14 does not have the n-type source layer 4 formed on its surface. The outermost p-type base layer 14 is used as a guard ring layer. Note that the outermost p-type base layer 14 as a guard ring layer is also connected to the source electrode 7.

An avalanche breakdown due to a high voltage applied carries a current of holes into the p-type base layer. An n-type source layer 4 formed on the surface of the outermost p-type base layer 14 would allow a parasitic bipolar transistor to operate, facilitating the current concentration. Then, as shown in FIG. 10, no n-type source layer on the surface of the outermost p-type base layer 14 can eliminate the parasitic bipolar transistor and can immediately drain the holes, thereby providing the high avalanche resistance.

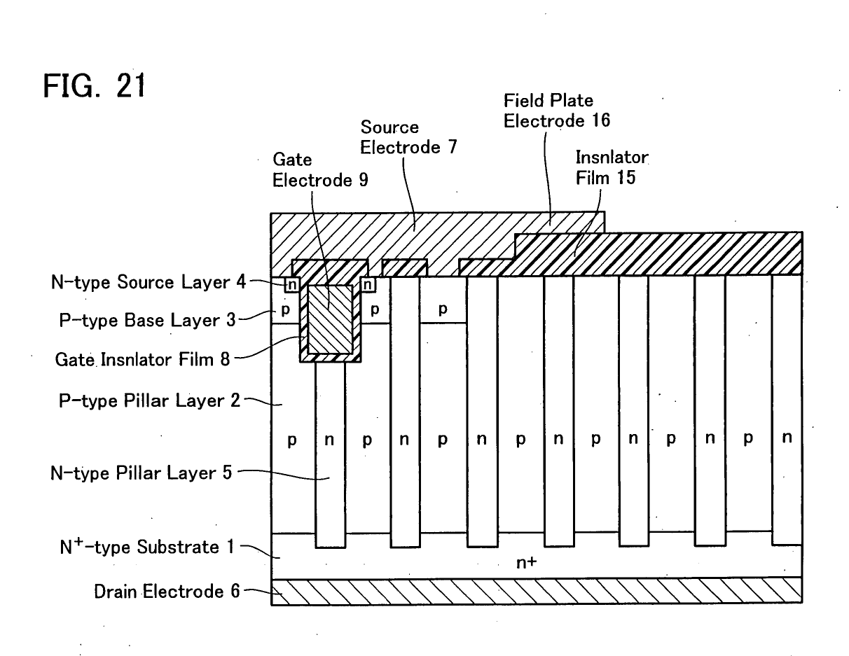

The p-type resurf layer 13 as in FIGS. 19 and 20 may be replaced by the end structure as in FIG. 21 in which a field plate electrode 16 is formed via an insulating film 15 on the pn pillar layers. The end structure can also provide the high breakdown voltage and is implementable. Compared to the end structure using the p-type resurf layer 13, the end structure using the field plate electrode 16 needs less thermal processes, which can suppress the decrease in the impurity concentration in the pn pillar layers.

Thus, although the present invention has been described with respect to the first to sixth embodiments thereof, the invention is not limited to those embodiments. For example, although the description has been given with respect to the case where the first conductivity type is the n-type and the second conductivity type is the p-type, the first conductivity type may be the p-type and the second conductivity type may be the n-type. Also, for example, the plane pattern of the gate portion or super junction structure of the MOSFET is not limited to the stripe, and may be a lattice or zigzag.

Although the description has been given with respect to the MOSFET using silicon (Si) as the semiconductor, the semiconductor may be, for example, a compound semiconductor such as silicon carbide (SiC) or gallium nitride (GaN), or a wide band gap semiconductor such as diamond. Although the description has been given with respect to the MOSFET having the super junction structure, the present invention applies to any device having the super junction structure, such as a combined device including SBD or MOSFET, and Schottky barrier diode, and a device such as SIT, or IGBT.

What is claimed is:

1. A semiconductor device comprising:
a semiconductor substrate of a first conductivity type;
pillar layers formed on the semiconductor substrate, the pillar layers comprising a first semiconductor pillar layer of a first conductivity type and a second semiconductor pillar layer of a second conductivity type which both have a strip cross section and are alternately formed in a first direction along a surface of the semiconductor substrate;
a first main electrode electrically connected to the first semiconductor substrate;
a semiconductor base layer of the second conductivity type selectively formed on a surface of one of the first semiconductor pillar layer and second semiconductor pillar layer;
a semiconductor diffusion layer of the first conductivity type selectively diffused into a surface of the semiconductor base layer;
a second main electrode formed in contact with the semiconductor base layer and semiconductor diffusion layer; and
a control electrode formed via an insulating film on a region over the semiconductor diffusion layer and first semiconductor pillar layer to form a channel between the semiconductor diffusion layer and first semiconductor pillar layer,
the semiconductor base layer having an impurity profile which is flat at least in the first direction.

2. The semiconductor device according to claim 1, wherein the semiconductor base layer is a semiconductor layer of the second conductivity type formed above a semiconductor layer forming said second semiconductor pillar layer and divided by said first semiconductor pillar layer.

3. The semiconductor device according to claim 1, wherein the semiconductor base layer is formed above the second semiconductor pillar layer.

4. The semiconductor device according to claim 3, wherein the semiconductor base layer is formed such that the semiconductor base layer and the second semiconductor pillar layer have flush side faces.

5. The semiconductor device according to claim 3, wherein the first semiconductor pillar layer and the semiconductor base layer have flush top faces, and
the control electrode is formed across the first semiconductor pillar layer and semiconductor diffusion layer to form the channel in a lateral direction.

6. The semiconductor device according to claim 1, wherein the control electrode is formed via the insulating film along the side face of the semiconductor base layer to form the channel in a vertical direction between the semiconductor diffusion layer and first semiconductor pillar layer.

7. The semiconductor device according to claim 6, wherein the control electrode is formed as a plurality of electrodes which have a vertical longitudinal direction and a plurality of which are formed for each of the first semiconductor pillar layers along the side face of the semiconductor base layer.

8. The semiconductor device according to claim 7, wherein an insulating film is embedded in a plurality of trenches formed at upper portion of each of the first semiconductor pillar layers, and the plurality of electrodes are respectively formed via the plurality of the insulating films.

9. The semiconductor device according to claim 1, further comprising a third semiconductor pillar layer of the first conductivity type which surrounds a periphery of a region including the first semiconductor pillar layer and second semiconductor pillar layer which are alternately formed.

10. The semiconductor device according to claim 9, wherein said third semiconductor pillar layer has a larger width than that of the first semiconductor pillar layer.

11. The semiconductor device according to claim 9, further comprising a fourth semiconductor pillar layer of the second conductivity type which surrounds a periphery of the third semiconductor pillar layer.

12. The semiconductor device according to claim 11, further comprising a fifth semiconductor pillar layer of the first conductivity type which surrounds a periphery of the fourth semiconductor pillar layer.

13. The semiconductor device according to claim 1, wherein the pillar layers are also formed in an end region outside a device region, and a semiconductor layer of the second conductivity type is formed on a surface of the pillar layers in the end portion.

14. The semiconductor device according to claim 1, wherein an outermost one of the semiconductor base layers that is formed at a boundary between the device region and the end region does not have the semiconductor diffusion layer formed therein and is used as a guard ring layer.

15. The semiconductor device according to claim 14, wherein said guard ring layer is connected to said second main electrode.

16. The semiconductor device according to claim 15, wherein the semiconductor base layer is formed above the second semiconductor pillar layer.

17. The semiconductor device according to claim 1, wherein the pillar layers are also formed in an end region outside a device region, an insulating film is formed on surfaces of the pillar layers in the end portion, and a field plate electrode is formed via the insulating film, the field plate electrode being electrically connected to the second main electrode or control electrode.

18. A method for manufacturing a semiconductor device comprising pillar layers formed on a first semiconductor layer of a first conductivity type, the pillar layers comprising a first semiconductor pillar layer of the first conductivity type and a second semiconductor pillar layer of a second conductivity type which are alternately formed in a first direction along a surface of the first semiconductor layer,
the method comprising:
growing an epitaxial layer for the pillar layers on the semiconductor substrate of the first conductivity type;
forming a semiconductor base layer of the second conductivity type on the epitaxial layer over a whole area of a device region by diffusion;
forming a trench which penetrates the semiconductor layer and reaches at least near a bottom of the epitaxial layer;
depositing in the trench a semiconductor layer of an opposite conductivity type to the epitaxial layer to form the pillar layer; and
forming a diffusion region, an insulating film, and an electrode in the semiconductor base layer divided by the trench to form the semiconductor device.
